(19) United States
(12) Patent Application Publication
(10) Pub. No.: US 2018/0337505 A1
(43) Pub. Date: Nov. 22, 2018

(54) MANUFACTURING PROCESS FOR KELVIN CONTACT ASSEMBLY HOUSING

(71) Applicant: JF MICROTECHNOLOGY SDN. BHD., Petaling Jaya (MY)

(72) Inventors: Wei Kuong FOONG, Petaling Jaya (MY); Kok Sing GOH, Petaling Jaya (MY); Shamal MUNDIYATH, Petaling Jaya (MY); Eng Kiat LEE, Petaling Jaya (MY); Mei Chen CHIN, Petaling Jaya (MY)

(73) Assignee: JF MICROTECHNOLOGY SDN. BHD., Petaling Jaya (MY)

(21) Appl. No.: 15/984,061

(22) Filed: May 18, 2018

(30) Foreign Application Priority Data
May 18, 2017 (MY) PI 2017701804

(51) Int. Cl. H01R 43/18; B23C 3/13; G01R 1/067; G01R 31/28

(52) U.S. Cl. CPC H01R 43/18; G01R 31/2886; G01R 1/06733; B23C 3/13

(57) ABSTRACT

A manufacturing process for a Kelvin contact assembly that achieves a high precision, near vertical motion at the end of the contact that contacts the device under test (DUT) by limiting horizontal motion of the contact close to where the contact contacts the DUT and comprising the steps of: preparing a blank of a housing of said contact assembly to the required profile; machining a plurality of lower slots in a row at a bottom side of said housing to a pre-determined depth; and machining a front slot and a back slot at a top side of said housing to a depth just reaching the depth of the said lower slots, said front and back slots parallel to each other, and perpendicular to said lower slots; such that two rows of virtual rectangular through-openings are formed from the juxtaposition of the said lower slots, front slot and back slot.

### FIELD OF INVENTION

The present invention relates to a manufacturing process for an electrical contact assembly in an integrated circuit testing apparatus, and specifically to one that achieves a high precision vertical motion by limiting horizontal motion of the contact near its contact end.

### BACKGROUND OF INVENTION

Kelvin contact testing in integrated circuit (IC) testing apparatuses typically use cantilever type contacts, where the contacts are formed as cantilevers, and part assembly types, where both contacts are assembled over an electrical insulator. With both these types, there is typically large accumulated tolerances, which makes assembly for fine pitching difficult.

Furthermore, kelvin contact assemblies that use housings to secure the cantilever contacts are complex and difficult to install. The end result is a long installation time that results in downtime.

Another problem of cantilever contact designs for kelvin testing apparatuses is that they produce wide tolerances that lead to uneven kelvin gaps and over-wiping issues on the device pads, as well as burr collision on the pin tips. Cantilever contact designs also have an issue with pin co-planarity. When cantilever pins are cut to shape, that creates its own tolerance distributions and contributes to unevenness or the so-called piano effect. This is an undesirable output that affects testing negatively.

What is needed in the art is a manufacturing process for a Kelvin contact assembly that overcomes the above disadvantages.

### SUMMARY OF INVENTION

The present invention seeks to overcome the aforementioned disadvantages by providing a manufacturing process for a Kelvin contact assembly that achieves a high precision, near vertical motion at the end of the contact that contacts the device under test (DUT) by limiting horizontal motion of the contact close to where the contact contacts the DUT.

This invention thus relates to a manufacturing process for two rows of virtual rectangular through-openings in an electrical contact assembly, comprising the following steps:
preparing a blank of a housing of said contact assembly to the required profile;
machining a plurality of lower slots in a row at a bottom side of said housing to a pre-determined depth;
machining a front slot and a back slot at a top side of said housing to a depth just reaching the depth of the said lower slots, said front and back slots parallel to each other, and perpendicular to said lower slots;
   such that two rows of virtual rectangular through-openings are formed from the juxtaposition of the said lower slots, front slot and back slot.

In a preferred embodiment of this invention, the machining of the lower slots, front slot and back slot is done using a CNC machine and an endmill. A Computer Aided Manufacturing (CAM) program is also used in addition to said CNC machine for the machining of the lower slots, front slot and back slot.

In another preferred embodiment, the housing is composed of a non-electrically conductive material, such as an engineering plastic.

In yet another preferred embodiment, the manufacturing process of this invention further comprises the step of gripping the housing in place with a mechanical means, such as a mechanical vise, during said machining of the lower slots, front slot and back slot.

Other objects and advantages will be more fully apparent from the following disclosure and appended claims.

### BRIEF DESCRIPTION OF DRAWINGS

FIG. 1 shows a blank of a contact assembly housing after a 1^{st} stage in an embodiment of this invention.

FIG. 2a shows a bottom view of a contact assembly after a 2^{nd} stage in an embodiment of this invention.

FIG. 2b shows a close-up bottom view of a contact assembly after a 2^{nd} stage in an embodiment of this invention.

FIG. 3a shows a top view of a contact assembly after a 3^{rd} stage in an embodiment of this invention.

FIG. 3b shows a close-up top view of a contact assembly after a 3^{rd} stage in an embodiment of this invention.

### DETAILED DESCRIPTION OF INVENTION

It should be noted that the following detailed description is directed to a manufacturing process for a Kelvin contact assembly, and is not limited to any particular size or configuration but in fact a multitude of sizes and configurations within the general scope of the following description.

### LIST OF NUMBERED ELEMENTS IN FIGURES

Lower Slots (10)
Lower Walls (15)
Front Slot (20)
Front Wall (25)
Back Slot (30)
Back Wall (35)
Bridge (40)
Top Housing (100)
Top Housing Top Side (101)
Top Housing Bottom Side (102)

The manufacturing process of this invention comprises 3 main stages.

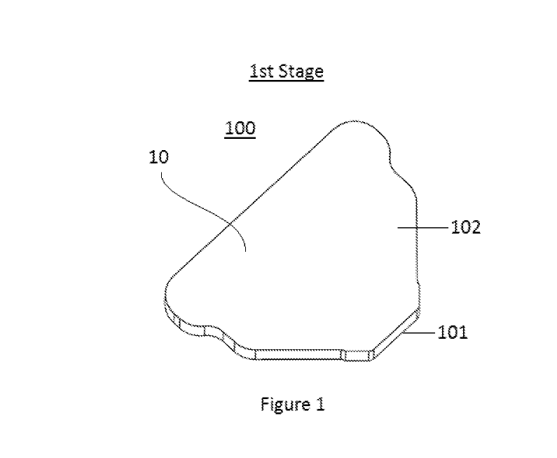

FIG. 1 shows a blank of a top housing (100) of said contact assembly that has been prepared by shaping to the required profile. In a preferred embodiment, the required profile is a flat piece of non-electrically conductive material such as an engineering plastic, with a top side (101) and a bottom side (102). The preparing and shaping of said blank comprises the said 1st stage of the manufacturing process of the present invention.

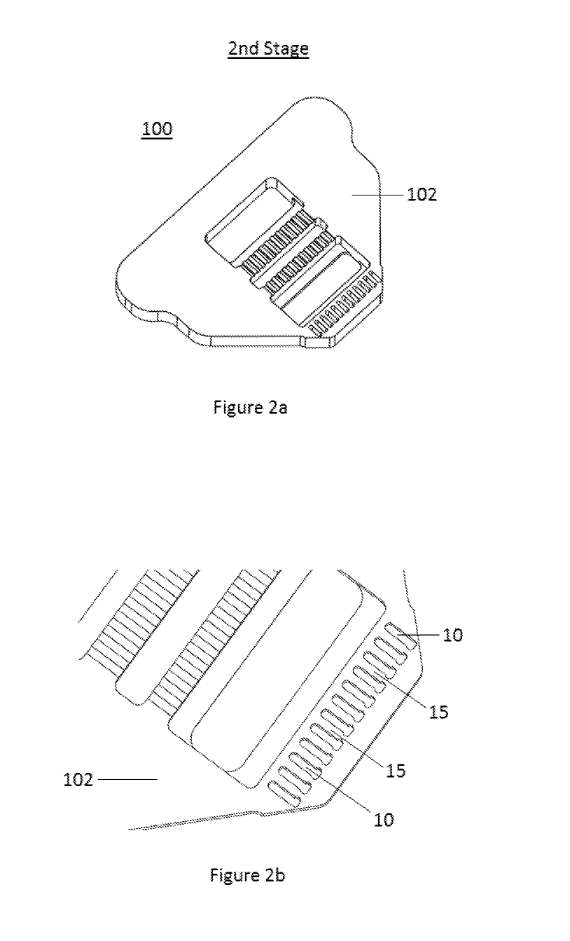

FIGS. 2a and 2b show the 2^{nd} stage of the manufacturing process of the present invention. In this said 2^{nd} stage, a plurality of lower slots (10) is machined to a pre-determined depth, and arranged side by side in a row near a front and on a bottom side (102) of said top housing (100). The said lower slots (10) run in a front to back direction. Lower walls (15) are hence formed from the said machining of the lower slots (10), which lower walls are interspersed between said lower slots (10).

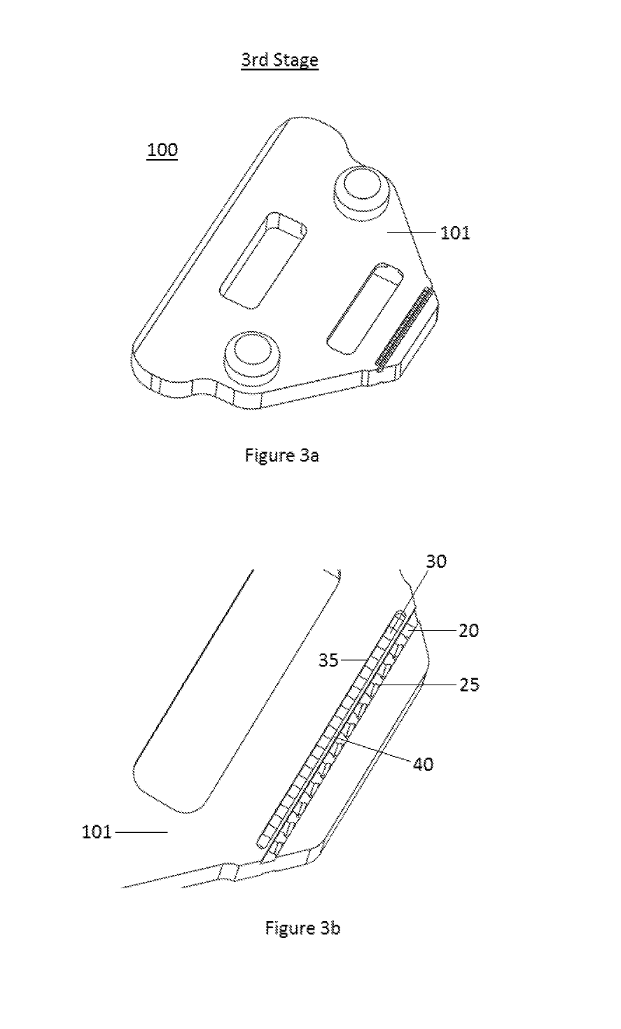

FIGS. 3a and 3b show the 3^{rd} stage of the manufacturing process of the present invention. In this said 3^{rd} stage, a front slot (20) and a back slot (30) are machined on a top side (101) of said top housing (100) just above the said lower slots (10), and to a depth that just reaches the said pre-determined depth of the lower slots (10). The said front slot (20) and back slot (30) are parallel to each other, but they are both perpendicular to the said lower slots (10). In this way, two rows of virtual rectangular through-openings are formed from the juxtaposition of the said lower slots (10), front slot (20) and back slot (30).

The use of the term “virtual” here merely means that the through-openings look rectangular only when viewed from a top down view. The “rectangular” quality of the through-openings is derived from the criss-crossing of the lower slots (10) against that of the front slot (20) and back slot (30). The terms “virtual rectangular through-opening” and “rectangular through-opening” will be used interchangeably and mean the same thing. The front row of these said 2 rows of rectangular through-openings is formed by the juxtaposition of the front slot (20) and a front portion of the row of lower slots (10). The back row of these said 2 rows of rectangular through-openings is formed by the juxtaposition of the back slot (30) and a rear portion of the row of lower slots (10).

Thus, the front slot (20) is formed between a front wall (25) and a bridge (40), and the back slot (30) is formed between a back wall (35) and said bridge (40). In other words, the said bridge (40) forms a divider between the said front slot (20) and back slot (30).

The front slot (20) and back slot (30) are thus stacked above the lower slots (10) and lower walls (15).

In a preferred embodiment, the height of the top housing (100) is around 1.5 mm. The depth of the lower slots (10) is around 1.2 mm. The depth of the front slot (20) and back slot (30) are around 0.3 mm.

In a preferred embodiment of this invention, the machining of the lower slots (10), front slot (20) and back slot (30) is done using a CNC machine and an endmill. A Computer Aided Manufacturing (CAM) program can also be used in addition to said CNC machine for the machining of the lower slots (10), front slot (20) and back slot (30).

In another preferred embodiment, the housing (100) is composed of a non-electrically conductive material, such as an engineering plastic.

In yet another preferred embodiment, the manufacturing process of this invention further comprises the step of gripping the housing in place with a mechanical means, such as a mechanical vise, during said machining of the lower slots (10), front slot (20) and back slot (30).

While several particularly preferred embodiments of the present invention have been described and illustrated, it should now be apparent to those skilled in the art that various changes and modifications can be made without departing from the scope of the invention. Accordingly, the following claims are intended to embrace such changes, modifications, and areas of application that are within the scope of this invention.

1. A manufacturing process for two rows of virtual rectangular through-openings in an electrical contact assembly, comprising the following steps:
preparing a blank of a housing of said contact assembly to the required profile;
machining a plurality of lower slots in a row at a bottom side of said housing to a pre-determined depth;
machining a front slot and a back slot at a top side of said housing to a depth just reaching the depth of the said lower slots, said front and back slots parallel to each other, and perpendicular to said lower slots;
such that two rows of virtual rectangular through-openings are formed from the juxtaposition of the said lower slots, front slot and back slot.

2. A manufacturing process for two rows of rectangular through-openings in an electrical contact assembly according to claim 1, wherein the said machining of the lower slots, front slot and back slot is done using a CNC machine and an endmill.

3. A manufacturing process for two rows of rectangular through-openings in an electrical contact assembly according to claim 2, wherein a Computer Aided Manufacturing program is used in addition to said CNC machine for the said machining of the lower slots, front slot and back slot.

4. A manufacturing process for two rows of rectangular through-openings in an electrical contact assembly according to claim 1, wherein the said housing is composed of a non-electrically conductive material.

5. A manufacturing process for two rows of rectangular through-openings in an electrical contact assembly according to claim 4, wherein the said non-electrically conductive material is an engineering plastic.

6. A manufacturing process for two rows of rectangular through-openings in an electrical contact assembly according to claim 1, also comprising the step of:
gripping said housing in place with a mechanical means during said machining of the lower slots, front slot and back slot.

7. A manufacturing process for two rows of rectangular through-openings in an electrical contact assembly according to claim 6, wherein the said mechanical means is a mechanical vise.
